(19) United States
(12) Patent Application Publication
(10) Pub. No.: US 2017/0141263 A1
(43) Pub. Date: May 18, 2017

(54) ULTRAVIOLET LIGHT-EMITTING DIODE

(71) Applicant: LEXTAR ELECTRONICS CORPORATION, HSINCHU (TW)

(72) Inventors: CHUNG-CHIEH YANG, TAICHUNG CITY (TW); TE-CHUNG WANG, TAICHUNG CITY (TW)

(21) Appl. No.: 15/347,031

(22) Filed: Nov. 9, 2016

(30) Foreign Application Priority Data
Nov. 12, 2015 (TW) 104137302

(51) Int. Cl. H01L 33/12; H01L 33/32; H01L 33/02; H01L 33/06

(52) U.S. Cl. CPC H01L 33/12; H01L 33/06; H01L 33/32; H01L 33/025

(57) ABSTRACT

The present invention relates to an ultraviolet light-emitting diode (LED), which includes a gradual superlattice layer. The gradual superlattice layer comprises a first superlattice layer and a second superlattice layer. The first superlattice layer includes a multi-layer structure having repetitive stacks of a unit formed by a first layer and a second layer. The second superlattice layer includes a multi-layer structure having repetitive stacks of a unit formed by a third layer and a fourth layer. The concentrations of aluminum in the first, second, third, and fourth layers decrease sequentially. By disposing the gradual superlattice layer, the quality of the epitaxial structure may be improved apparently.

### FIELD OF THE INVENTION

The present invention relates generally to an ultraviolet light-emitting diode (LED), and particularly to an ultraviolet LED capable of improving the quality of epitaxial structure.

### BACKGROUND OF THE INVENTION

Technologies advance day by day. The LED industry is developing prosperously. LEDs are widely used in many applications, including lighting, medical, sterilizing, water purifying, and high-density optical recording applications. In particular, ultraviolet LEDs attract additional attention.

Currently, the group-III nitrides are mostly adopted as the semiconductor material for forming LEDs. Thanks to their epitaxial characteristics, the group-II nitrides are applied extensively to electronic equipment or light-emitting devices. Thereby, the epitaxy of the group-III nitrides has become the dominant factor determining the efficiency of electronic equipment or light-emitting devices. While growing a group-III nitride on a substrate, dislocations are easily occurred. The dislocations affect the quality of the epitaxial structure of LEDs. Consequently, the problem of inferior light-emitting efficiency for LEDs may occur.

In order to improve the quality of the epitaxial structure of LEDs, while growing a nitride semiconductor layer on a substrate, various buffer layer structures are proposed for mitigating the defects caused by the difference between the epitaxial structure of the nitride semiconductor layer and the substrate, dislocations, or the differences in thermal expansion coefficients.

Presently, as technologies progress in the LED industry, the output power is improved, the efficiency is increased, the lifetime is extended, and the cost is lowered. Thereby, ultraviolet LEDs have become ready to enter the application market. The fabrication of an ultraviolet LED starts from growing on a substrate. For avoiding light absorption, the gallium nitride (GaN) material, which is adopted for growing a blue LED, is changed to the aluminum nitride (AlN) material. Nonetheless, the lattice mismatch problem still exists. The problem will deteriorate the quality of the epitaxial structure of ultraviolet LEDs and thus further lowering their light-emitting efficiency.

Accordingly, the present invention provides an ultraviolet LED that improves lattice matching of the group-III nitrides and solves the problem of dislocations. Thereby, the drawbacks in the prior art may be solved and the quality of the epitaxial structure of LEDs may be enhanced.

### SUMMARY

An objective of the present invention is to provide an ultraviolet LED, which uses a gradual superlattice structure to improve the quality of the epitaxial structure of LEDs.

Another objective of the present invention is to provide an ultraviolet LED, which uses a multi-layer n-type semiconductor structure doped with silicon having different concentrations for improving the electrical property and thus improving the light-emitting efficiency of LEDs.

In order to achieve the above objectives and efficacies, the present invention provides an ultraviolet LED, which includes a buffer layer on a substrate. A gradual superlattice layer is disposed on the buffer layer. The gradual superlattice layer comprises a first superlattice layer and a second superlattice layer. The first superlattice layer includes a multi-layer structure having repetitive stacks of a unit formed by a first layer and a second layer. The second superlattice layer includes a multi-layer structure having repetitive stacks of a unit formed by a third layer and a fourth layer. By controlling the concentrations of aluminum in the first, second, third, and fourth layers to decrease sequentially, lattice defects may be reduced and thus improving the epitaxial quality.

A superlattice is a multi-layer crystal grown alternately by two thin-film materials having different properties. A user may control the period length by controlling the thicknesses of the thin films. Besides, because the period length is much longer than the lattice length, the energy band becomes wider, and thus enabling accommodation of more electrons than normal lattices. Thereby, it is called a superlattice.

According to an embodiment, the concentration of aluminum in the first layer is smaller than that in the buffer layer.

According to an embodiment, the buffer layer includes aluminum nitride (AlN).

According to an embodiment, the concentration of aluminum in the fourth layer is greater than or equal to that in the n-type semiconductor layer.

According to an embodiment, the n-type semiconductor layer includes aluminum gallium nitride (AlGaN).

According to an embodiment, the buffer layer further comprises a first buffer layer and a second buffer. The second buffer layer is undoped aluminum nitride (u-AlN).

In addition, an n-type semiconductor layer according to the present invention comprises a first n-type semiconductor layer, a second n-type semiconductor layer, and a third n-type semiconductor layer, in the order of epitaxial growth. The doping concentration in the first n-type semiconductor layer is greater than that in the third n-type semiconductor layer. The second n-type semiconductor layer is undoped. By changing the doping concentrations, the electrical characteristics are improved and the light-emitting efficiency of LEDs is increased.

According to an embodiment, the first and third n-type semiconductor layers are doped with silicon.

According to an embodiment, the thickness of the first n-type semiconductor layer is greater than the thicknesses of the second and third n-type semiconductor layers.

According to an embodiment, the thickness of the first n-type semiconductor layer is greater than 1 um; the thicknesses of the second and third n-type semiconductors layers are less than 0.2 um.

According to an embodiment, the gradual superlattice is doped with silicon.

### BRIEF DESCRIPTION OF THE DRAWINGS

FIG. 1 shows a schematic diagram of the ultraviolet LED according to the first embodiment of the present invention;

FIG. 2 shows a schematic diagram of improvements in the ultraviolet LED according to the first embodiment of the present invention;

FIG. 3 shows a schematic diagram of the ultraviolet LED according to the second embodiment of the present invention; and

FIG. 4 shows a schematic diagram of the ultraviolet LED according to the third embodiment of the present invention.

### DETAILED DESCRIPTION

In order to make the structure and characteristics as well as the effectiveness of the present invention to be further understood and recognized, the detailed description of the present invention is provided as follows along with embodiments and accompanying figures.

The fabrication of an ultraviolet LED starts from growing on a substrate. For avoiding light absorption, the gallium nitride material, which is adopted for growing a blue LED, is changed to the aluminum nitride (AlN) material. Nonetheless, the lattice mismatch problem still exists. The problem will deteriorate the quality of the epitaxial structure of ultraviolet LEDs and thus further lowering their light-emitting efficiency. Thereby, the present invention provides an ultraviolet LED for improving the drawbacks in the prior art. The ultraviolet LED includes UVA, UVB, and UVC.

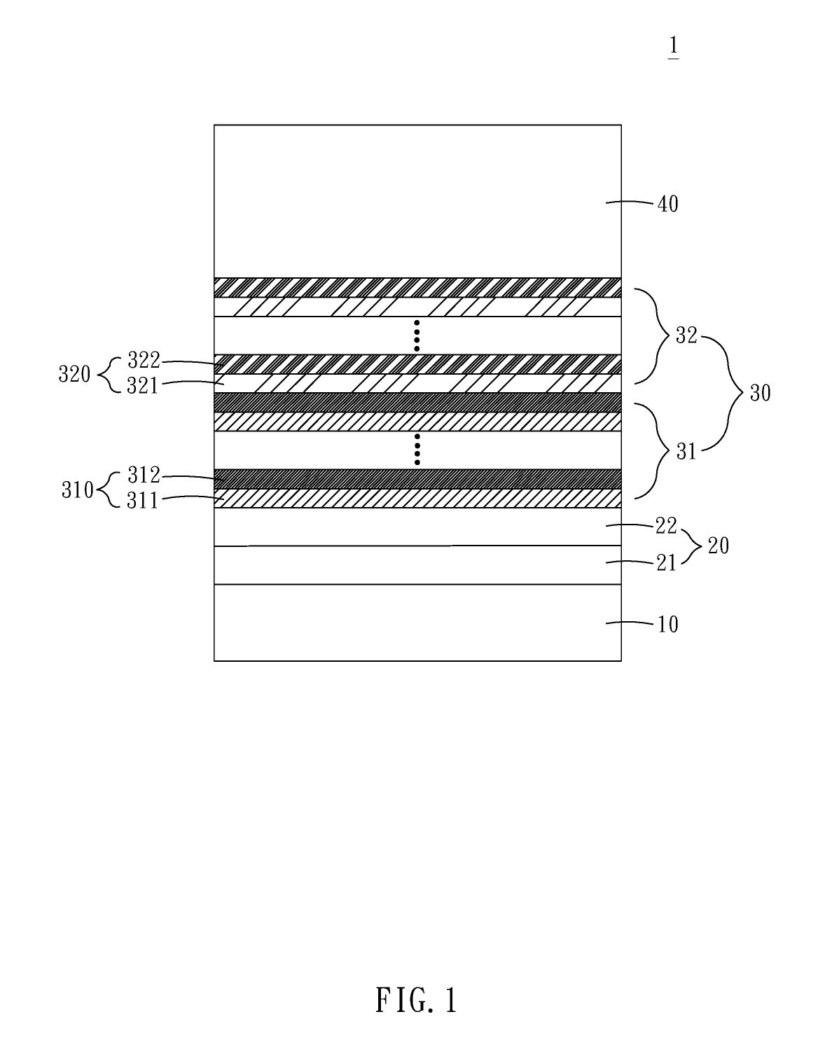

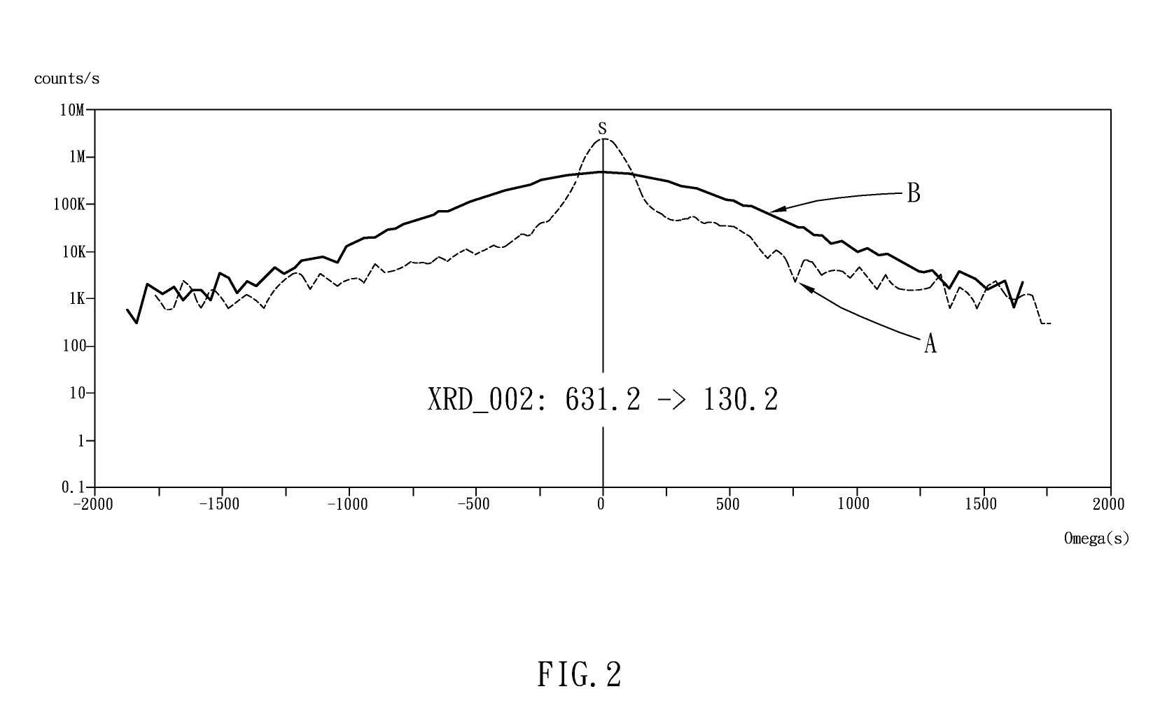

Please refer to FIGS. 1 and 2, which show schematic diagrams of the ultraviolet LED and improvements according to the first embodiment of the present invention. As shown in the figures, the present embodiment provides an epitaxial structure 1 of the ultraviolet LED. The epitaxial structure 1 comprises a substrate 10, a buffer layer 20, a gradual superlattice 30, and an n-type semiconductor layer 40. The gradual superlatticc layer 30 comprises a first superlattice layer 31 and a second superlattice layer 32. According to the present invention, the gradual superlattice layer 30 is used for improving the quality of the epitaxial structure 1 of the ultraviolet LED.

According to the present embodiment, the material of the substrate 10 may be sapphire, glass, or ceramics. According to the present embodiment, a sapphire substrate is adopted for example. The buffer 20 is disposed on the substrate 10. The buffer layer 20 further comprises a first buffer layer 21 and a second buffer layer 22. The first buffer layer 21 is doped aluminum nitride (AlN); the second buffer layer 22 is undoped aluminum nitride (u-AlN). The second buffer layer 22 is located on the first buffer 21. On the buffer layer 20, a first superlattice layer 31 and a second superlattice layer 32 are disposed sequentially. The first superlattice layer 31 includes a multi-layer structure. A first layer 311 and a second layer 312 are stacked sequentially to form a unit 300. Then the unit 300 is stacked repetitively to form the first superlattice layer 31. Likewise, a third layer 321 and a fourth layer 322 are stacked sequentially to form a unit 320. Then the unit 320 is stacked repetitively to form the second superlattice layer 312. Next, the n-type semiconductor layer 40 is disposed on the gradual superlattice layer 30.

There are differences in the main layers of the gradual superlattice layer 30. The aluminum concentration of the first layer 311 of the first superlattice layer 31 is greater than or equal to that of the second layer 312 of the first superlattice layer 31. The aluminum concentration of the second layer 312 of the first superlattice layer 31 is greater than or equal to that of the third layer 321 of the second superlattice layer 32. The aluminum concentration of the third layer 321 of the second superlattice layer 32 is greater than or equal to that of the fourth layer 322 of the second superlattice layer 32. The concentrations of aluminum in the first, second, third, and fourth layers 311, 312, 321, 322 decrease sequentially. The thicknesses of the first, second, third, and fourth layers 311, 312, 321, 322 are approximately between 10 Å and 12 Å.

In addition, the concentration of aluminum in the first later 311 of the first superlattice layer 31 is smaller than or equal to that in the buffer layer 20. The buffer layer 20 includes aluminum nitride (AlN). The concentration of aluminum in the second layer 322 of the second superlattice layer 32 is greater than or equal to that in the n-type semiconductor layer 40. The concentration of aluminum in the gradual superlattice layer 30 is between the concentration of aluminum in the buffer layer 20 and the concentration of aluminum in the n-type semiconductor layer 40. The n-type semiconductor layer includes aluminum gallium nitride (AlGaN).

According to the prior art, the aluminum nitride (AlN) material grown on a substrate will encounter the lattice mismatch problem, which deteriorates the quality of the epitaxial structure of the ultraviolet LEDs and hence leads to inferior light-emitting efficiency. The reason is that if the difference in the concentrations of aluminum between adjacent stacked layers is too large, defects such as dislocations and difference in stress will result. Accordingly, according to the present embodiment, the gradual superlattice layer 30 is disposed between the buffer layer 20 and the n-type semiconductor layer 30. The concentration of aluminum in the gradual superlattice layer 30 is between the concentration of aluminum in the buffer layer 20 and the concentration of aluminum in the n-type semiconductor layer 40. The gradual superlattice layer 30 comprises the first and second lattice layers 31, 32. The first lattice layer 31 comprises the first and second layers 311, 312. The second lattice layer 32 comprises the third and fourth layers 321, 322. The concentrations of aluminum in the first, second, third, and fourth layers 311, 312, 321, 322 decrease sequentially. In this way, the difference in the concentrations of aluminum between adjacent layers will not be too large, which is beneficial for releasing stress and blocking the increasing of dislocations. Please refer to FIG. 2, which shows an X-ray diffraction of the epitaxial structure according to the present embodiment. According to the figure, it is observed that the result is improved from line B (without gradual superlattice layer) to line A (with the gradual superlattice layer 30). It is evident that the quality of the epitaxial structure of the ultraviolet LEDs has been improved. Besides, according to the present embodiment, the quantity of the stacked units of the first and second layers 311, 312 and the quantity of the stacked units of the third and fourth layers 321, 322 are not limited. The quantity may be increased or decreased according to the stress and dislocations to be adjusted.

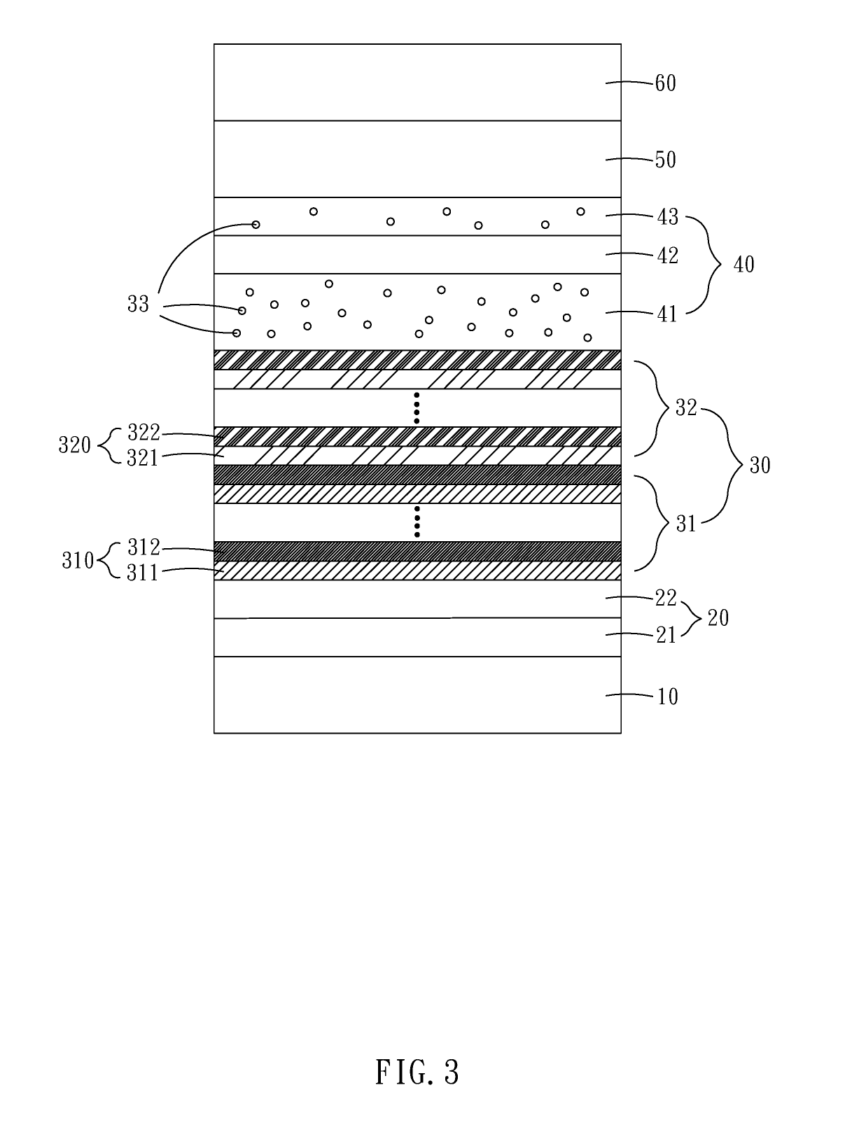

Please refer to FIG. 3, which shows a schematic diagram of the ultraviolet LED according to the second embodiment of the present invention. As shown in the figure, the difference between the present embodiment and the first one is that the n-type semiconductor layer 40 according to the present embodiment includes the aluminum gallium nitride (AlGaN) material. According to the order of epitaxy, the ultraviolet LED comprises a first n-type semiconductor layer 41, a second n-type semiconductor layer 42, and a third n-type semiconductor layer 43. The second n-type semiconductor 42 is undoped. The doping concentration of the first n-type semiconductor layer 41 is greater than that of the third n-type semiconductor layer 43. In addition, the first and third n-type semiconductor layers are doped with silicon 33. Moreover, the thickness of the first n-type semiconductor layer 41 is greater than the thickness of the second n-type semiconductor layer 42 and the thickness of the third n-type semiconductor layer 43. According to the present embodiment, the thickness of the first n-type semiconductor layer 41 is greater than 1 um; thicknesses of the second and third n-type semiconductor layers 42, 43 are less than 0.2 um. Then a light-emitting layer 50 (multiple quantum well, MQW) is disposed on the third n-type semiconductor layer 43 of the n-type semiconductor layer 40; a p-type semiconductor layer 60 is disposed on the light-emitting layer 50.

The n-type semiconductor layer 40 according to the present embodiment comprises the first, second, and third n-type semiconductor layers 41, 42, 43. The reason for this structure is that if the light-emitting layer 50 is stacked directly on the n-type semiconductor layer doped with silicon, the quality of the epitaxial structure of the light-emitting layer 50 will be affected owing to excessive concentration of silicon in the n-type semiconductor layer. As a result, the light-emitting efficiency will be influenced. Accordingly, the second n-type semiconductor layer undoped with silicon is disposed on the first n-type semiconductor layer 41 for improving the quality of the epitaxial structure of the light-emitting layer 50. In addition, for preventing overly few electrons entering the light-emitting layer 50 from the n-type semiconductor layer 40, the third n-type semiconductor layer 43 doped with silicon is further disposed on the second n-type semiconductor layer 42 for offsetting the drawback of overly few electrons. Moreover, the thicknesses of the second and third n-type semiconductor layers 42, 43 are set to be sufficient to adjust the electrical characteristics of the first n-type semiconductor layer 41. Thereby, their thicknesses will not exceed that thickness of the first n type semiconductor layer 41.

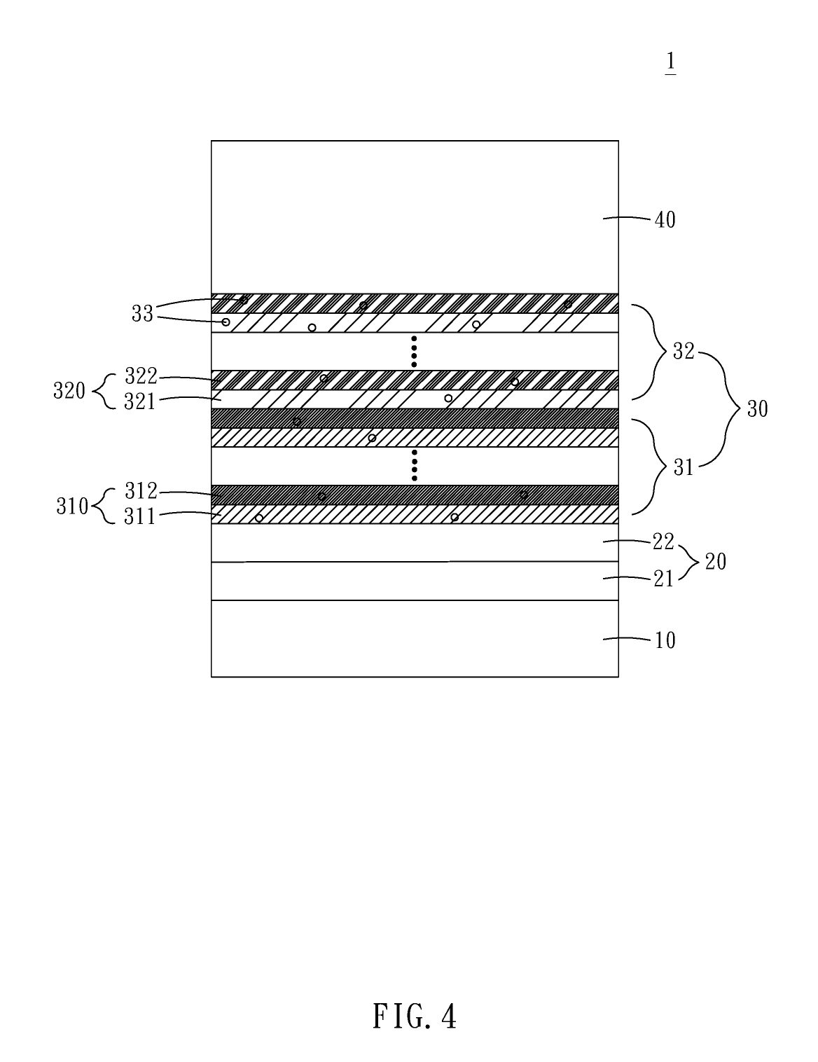

Please refer to FIG. 4, which shows a schematic diagram of the ultraviolet LED according to the third embodiment of the present invention. As shown in the figure, according to the present embodiment, the gradual superlattice layer 30 is further doped with silicon with the purpose of facilitating epitaxial growth on the second buffer layer 22 (an undoped aluminum nitride (u-AlN) layer) of the buffer layer 20.

To sum up, the present invention provides an ultraviolet LED. The gradual superlattice layer is disposed between the buffer layer and the n-type semiconductor layer. The gradual superlattice layer comprises a first superlattice layer and a second superlattice layer. The first superlattice layer includes a multi-layer structure having repetitive stacks of a unit formed by a first layer and a second layer. The second superlattice layer includes a multi-layer structure having repetitive stacks of a unit formed by a third layer and a fourth layer. The concentrations of aluminum in the first, second, third, and fourth layers decrease sequentially. In this way, the difference in the concentrations of aluminum between adjacent layers will not be too large, which is beneficial for releasing stress and blocking the increasing of dislocations. In addition, the n-type semiconductor layer comprises a first n-type semiconductor layer, a second n-type semiconductor layer, and a third n-type semiconductor. The doping concentration of silicon in the first n-type semiconductor layer is greater than that in the third n-type semiconductor layer. The second n-type semiconductor layer is undoped with silicon. The second and third n-type semiconductor layers are mainly used for adjusting the electrical characteristics of the first n-type semiconductor layer. Furthermore, the gradual superlattice layer is lightly doped with silicon, which is beneficial to the epitaxial growth on the second buffer layer (an undoped aluminum nitride (u-AlN) layer) of the buffer layer.

Accordingly, the present invention conforms to the legal requirements owing to its novelty, nonobviousness, and utility. However, the foregoing description is only embodiments of the present invention, not used to limit the scope and range of the present invention. Those equivalent changes or modifications made according to the shape, structure, feature, or spirit described in the claims of the present invention are included in the appended claims of the present invention.

What is claimed is:

1. An ultraviolet light-emitting diode, comprising:
a substrate;
a buffer layer, disposed on said substrate;
a gradual superlattice layer, disposed on said buffer layer, comprising:
a first superlattice layer, including a multi-layer structure having repetitive stacks of a unit formed by a first layer and a second layer; and
a second superlattice layer, including a multi-layer structure having repetitive stacks of a unit formed by a third layer and a fourth layer; and
an n-type semiconductor layer, disposed on said gradual superlattice layer;
where the concentrations of aluminum in said first layer, said second layer, said third layer, and said fourth layer decrease sequentially.

2. The ultraviolet light-emitting diode of claim 1, wherein said buffer layer further includes a first buffer layer and a second buffer layer, and said second buffer layer is undoped aluminum nitride.

3. The ultraviolet light-emitting diode of claim 1, wherein said n-type semiconductor layer comprises a first n-type semiconductor layer, a second n-type semiconductor layer, and a third n-type semiconductor layer, in the order of epitaxial growth; the doping concentration in said first n-type semiconductor layer is greater than the doping concentration in said third n-type semiconductor layer; and said second n-type semiconductor layer is undoped.

4. The ultraviolet light-emitting diode of claim 1, wherein the concentration of aluminum in said first layer is smaller than or equal to the concentration of aluminum in said buffer layer.

5. The ultraviolet light-emitting diode of claim 4, wherein said buffer layer further includes a first buffer layer and a second buffer layer, and said second buffer layer is undoped aluminum nitride.

6. The ultraviolet light-emitting diode of claim 4, wherein said n-type semiconductor layer comprises a first n-type semiconductor layer, a second n-type semiconductor layer, and a third n-type semiconductor layer, in the order of epitaxial growth; the doping concentration in said first n-type semiconductor layer is greater than the doping concentration in said third n-type semiconductor layer; and said second n-type semiconductor layer is undoped.

7. The ultraviolet light-emitting diode of claim 4, wherein said buffer layer includes aluminum nitride.

8. The ultraviolet light-emitting diode of claim 1, wherein the concentration of aluminum in said fourth layer is greater than or equal to the concentration of aluminum in said n-type semiconductor layer.

9. The ultraviolet light-emitting diode of claim 8, wherein said n-type semiconductor layer includes aluminum gallium nitride.

10. The ultraviolet light-emitting diode of claim 8, wherein said buffer layer further includes a first buffer layer and a second buffer layer, and said second buffer layer is undoped aluminum nitride.

11. The ultraviolet light-emitting diode of claim 8, wherein said n-type semiconductor layer comprises a first n-type semiconductor layer, a second n-type semiconductor layer, and a third n-type semiconductor layer, in the order of epitaxial growth; the doping concentration in said first n-type semiconductor layer is greater than the doping concentration in said third n-type semiconductor layer; and said second n-type semiconductor layer is undoped.

12. The ultraviolet light-emitting diode of claim 11, wherein said first n-type semiconductor layer and said third n-type semiconductor layer are doped with silicon.

13. The ultraviolet light-emitting diode of claim 11, wherein the thickness of said first n-type semiconductor layer is greater than the thicknesses of said second n-type semiconductor layer and said third n-type semiconductor layer.

14. The ultraviolet light-emitting diode of claim 11, wherein the thickness of said first n-type semiconductor layer is greater than 1 micrometer, and the thicknesses of said second n-type semiconductor layer and said third n-type semiconductor layer are smaller than 0.2 micrometer.

15. The ultraviolet light-emitting diode of claim 1, wherein said gradual superlattice layer is doped with silicon.
